(19) United States
(12) Patent Application Publication
(10) Pub. No.: US 2026/0227459 A1
(43) Pub. Date: Aug. 6, 2026

(54) ELECTRONIC CIRCUITS AND METHODS FOR MONITORING LEAKAGE CURRENT

(71) Applicant: Infineon Technologies AG, Neubiberg (DE)

(72) Inventors: Christof Marc Thoma, Villach (AT); Christian Djelassi-Tscheck, Villach (AT)

(21) Appl. No.: 19/451,753

(22) Filed: Jan. 16, 2026

(30) Foreign Application Priority Data
Feb. 6, 2025 (DE) 102025104390.6

(51) Int. Cl. G01R 31/52; B60L 3/00; G01R 19/00; G01R 19/165

(52) U.S. Cl. CPC G01R 31/52; B60L 3/0069; G01R 19/0092; G01R 19/16571; B60L 2260/22

(57) ABSTRACT

CURRENT

An electronic circuit and a method is provided for detecting a leakage current in a second circuit. According to an embodiment, the electronic circuit comprises timing circuitry and monitoring circuitry, wherein the timing circuitry is configured to automatically activate the monitoring circuitry at time intervals set by the timing circuity to repeatedly measure a measurement current indicative of a leakage; and wherein the monitoring circuitry is configured to compare the measurement current measured at each interval to a leakage threshold current, wherein when the measurement current exceeds the leakage threshold current, the monitoring circuitry is configured to send an indication to control circuitry of the second circuit.

### TECHNICAL FIELD

The present application relates to methods and systems for monitoring leakage current.

### BACKGROUND

Corrosion associated with leakage currents may occur in electronic circuits and systems. Hence, there is a need to efficiently monitor leakage currents.

### SUMMARY

According to an embodiment, an electronic circuit is provided for detecting a leakage current in a second circuit, the electronic circuit comprising: timing circuitry and monitoring circuitry;
wherein the timing circuitry is configured to automatically activate the monitoring circuitry at time intervals set by the timing circuity to repeatedly measure a measurement current indicative of a leakage; and
wherein the monitoring circuitry is configured to compare the measurement current measured at each interval to a leakage threshold current, wherein when the measurement current exceeds the leakage threshold current, the monitoring circuitry is configured to send an indication to control circuitry of the second circuit.

According to another embodiment, a system is provided, the system comprising an electronic circuit and a second circuit; the electronic circuit comprising: timing circuitry and monitoring circuitry; wherein the timing circuitry is configured to automatically activate the monitoring circuitry at time intervals set by the timing circuity to repeatedly measure a measurement current indicative of a leakage; and
wherein the monitoring circuitry is configured to compare the measurement current measured at each interval to a leakage threshold current, wherein when the measurement current exceeds the leakage threshold current, the monitoring circuitry is configured to send an indication to control circuitry of the second circuit.

According to another embodiment, a vehicle is provided, the vehicle comprising an electronic circuit or a system. The system comprises: the electronic circuit and a second circuit. The electronic circuit comprises:
timing circuitry and monitoring circuitry;
wherein the timing circuitry is configured to automatically activate the monitoring circuitry at time intervals set by the timing circuity to repeatedly measure a measurement current indicative of a leakage; and
wherein the monitoring circuitry is configured to compare the measurement current measured at each interval to a leakage threshold current, wherein when the measurement current exceeds the leakage threshold current, the monitoring circuitry is configured to send an indication to control circuitry of the second circuit.

According to another embodiment, a use of an electronic circuit is provided. The use is for leakage current detection in a vehicle. The electronic circuit comprises:
timing circuitry and monitoring circuitry;
wherein the timing circuitry is configured to automatically activate the monitoring circuitry at time intervals set by the timing circuity to repeatedly measure a measurement current indicative of a leakage; and
wherein the monitoring circuitry is configured to compare the measurement current measured at each interval to a leakage threshold current, wherein when the measurement current exceeds the leakage threshold current, the monitoring circuitry is configured to send an indication to control circuitry of the second circuit.

According to another embodiment, a use of a system is provided. The use is for leakage current detection in a vehicle. The system comprises: an electronic circuit and a second circuit. The electronic circuit comprises:
timing circuitry and monitoring circuitry;
wherein the timing circuitry is configured to automatically activate the monitoring circuitry at time intervals set by the timing circuity to repeatedly measure a measurement current indicative of a leakage; and
wherein the monitoring circuitry is configured to compare the measurement current measured at each interval to a leakage threshold current, wherein when the measurement current exceeds the leakage threshold current, the monitoring circuitry is configured to send an indication to control circuitry of the second circuit.

According to another embodiment, a method is provided, the method to be carried out by an electronic circuit, wherein the electronic circuit comprises timing circuitry and monitoring circuitry. The method comprises:
automatically activating the monitoring circuitry, by the timing circuitry, at time intervals set by the timing circuity to repeatedly measure a measurement current indicative of a leakage; and
comparing, by the monitoring circuitry, the measurement current measured at each interval to a leakage threshold current indicative of a leakage state,
sending an indication by the monitoring circuitry to control circuitry of a second circuit when the measurement current exceeds the leakage threshold current.

The above summary is merely a brief overview over some features of some embodiments and is not to be construed as limiting in any way, as other embodiments may include different features than the ones given above.

### BRIEF DESCRIPTION OF THE DRAWINGS

FIG. 1 is a diagram illustrating an electronic circuit 100 for detecting a leakage current in a second circuit.

FIG. 2 is a more detailed diagram (as to the one in FIG. 1) illustrating an electronic circuit 200 for detecting a leakage current in a second circuit.

FIG. 3a is a flowchart of a method 300a according to an embodiment.

FIG. 3b is a flowchart of a method 300b according to an embodiment.

FIG. 4 is a flowchart of a method 400 according to an embodiment.

FIG. 5 is a timing diagram 500 according to an embodiment.

FIG. 6 is a state diagram 600 according to an embodiment.

### DETAILED DESCRIPTION

When corrosion occurs in electronic circuits, (e.g., power circuits; control circuitry of vehicles), a low leakage current can flow through a corroded or partially conductive pathway between the affected component of the circuit and the circuit's ground. The leakage current can be particularly low when corrosion has begun but has not yet created a fully conductive path, resulting in a high-resistance circuit.

Very low leakage current (e.g., in a double-digit milliampere range) may be used as an early indicator in corrosion monitoring systems to detect subtle degradation or the onset of corrosion. By identifying such low-level currents, the system can provide a warning before severe damage or failure can occur.

High ohmic resistance to ground in this case may be formed by partially corroded materials, moisture, or other contaminants that allow only a small leakage current. The “high ohmic” resistance in this case typically is in the range of megaohms (MΩ), requiring sensitive detection systems to measure the low leakage currents accurately. Measuring the low leakage currents accurately can help in early diagnosis and preventive maintenance of circuitry prone to corrosion.

One example of circuitry prone to corrosion may be control circuitry of vehicles. A vehicle typically comprises multiple electronic parts mounted on a PCB (Printed Circuit Board). Any electronic part and units on a PCB, including connection cables, and connectors themselves, and alike components can suffer from the very low current leakage (high ohmic resistance to the ground) which can worsen over time, especially because of humidity. Corrosive worsening over time may be referred to as “active corrosion”, or in other words, corrosion that changes over time. If active corrosion is undetected over a long time, severe damage or failure can occur (e.g., a fire in a car).

To observe an increase leakage current due to active corrosion, which is typically in a range of tens of milliampere (double-digit milliampere range), corrosion monitoring is not easy. One problem relates to the nature of circuitry prone to corrosion, for example, control circuitry of vehicles, which are designed to manage significant electrical loads. For example, the operation of high side switches (HSS) or bypass devices in vehicles, and their diagnostic often involve currents in the range of double-digit amperes, while monitoring active corrosion requires detection of much smaller currents (e.g., double-digit milliampere range). Other problems associated with monitoring active corrosion relate to distinguishing the leakage current from load current. For example, the detection may be the most efficient during, e.g., a parking mode of a vehicle, where no current is expected to flow. For example, nominal current of a typical HSS switch may be up to 40 A (through 0.8 mOhm load), while leakage current caused by active corrosion may be in the order of 50 mA during car parking. However, constant detection or sensing during the parking mode (low power mode) would decrease the battery capacity of the vehicle. This is because the monitoring circuitry can draw a significant amount of power to monitor leakage current. Hence, there is a need to detect leakage current more efficiently, both in the sense of accuracy related to high contrast between nominal load current and leakage current, and in the sense of reducing power consumption needed to monitor leakage current.

A low power mode (or in other words, a parking mode, a passive mode, an idle mode or a standby mode) may refer to a power state in which a system or circuit remains active but operates at reduced power consumption with one or more components being switched off. Hence, in low power mode the system or the circuit typically performs only essential functions or waiting for specific triggers to resume full operation. The terms “a low power mode”, “a parking mode”, “a passive mode”, “an idle mode” or “a standby mode” are used interchangeably in this application.

A low power mode relates to the operation of the second circuit (e.g., a power circuit of the vehicle), while reduced power consumption during monitoring of leakage current relates to the operation of the electronic circuit or the system of this application. The relationship between the low power mode and the reduced power consumption is such that the monitoring of the leakage current can be implemented in the lower power mode, while the power consumption during monitoring of the leakage current in said lower power mode can be reduced due to the timing circuitry managing the monitoring automatically. Hence, such an automatic monitoring leads to reduced power consumption by the electronic circuit or the system of this application.

Low power mode may be used to preserve energy, especially in systems powered by the vehicle's battery, while maintaining readiness to detect and respond to potential corrosion-related events. During this mode, the system might monitor low-level parameters such as leakage currents or environmental conditions without initiating intensive diagnostics or active interventions. Low power mode may comprise reduced functionality, such as periodic sampling of signals, maintaining a low-power state in sensors and microcontrollers (i.e., a state when some of the functions or components are powered off), and storing minimal data until a threshold event, such as increased leakage current or a change in resistance, activates full system.

In the following, various embodiments will be described in detail referring to the attached drawings. These embodiments are given by way of example only and are not to be construed as limiting in any way.

Features from different embodiments may be combined to form further embodiments. Variations, modifications or details described with respect to one of the embodiments are also applicable to other embodiments and will not be described repeatedly.

Some terms used herein will be explained in the following.

A High Side Switch (HSS) may refer to an electronic component used to control the flow of current from the positive terminal (high side) of a power supply to a load. It may act as an intelligent switch, typically implemented using power transistors like MOSFETs, and particularly, DMOS. HSS may be used in automotive, industrial, and consumer electronics applications. HSSs can achieve quiescent current levels as low as <1 μA to a few μA in a standby mode. In automotive applications, HSS devices often need to remain operational during low-power states to wake up the system without draining the battery. HSS devices can limit current consumption during switching events to microampere levels. Connection paths switched by the HSS can be prone to corrosion and hence leakage current may occur. This leakage current may be monitored by the methods and systems of the current application.

A bypass device may be used in electric vehicle for rerouting electrical current. A bypass device typically includes relays, diodes, and resistors. A bypass device can replace or work alongside a high-side switch (HSS) for applications such as isolating faulty circuits, maintaining power flow during system maintenance, or managing low-power operations like charging. Battery charging occurs typically in a low power mode (i.e., during parking). Hence, low power mode is also referred to as a parking mode in some examples of this application. By providing an alternative current path, A bypass device can enhance reliability of the second circuit (such as a power circuit of an electric vehicle), reducing stress on the HSS. In both cases, if a bypass device is used in addition to HSS or as an alternative to it, connection paths switched by the bypass device can be prone to corrosion and hence leakage current may occur. This leakage current may be monitored by the methods and systems of the current application.

A low current consumption may be defined by a microampere current level or lower. Depending on an ISO standard (e.g., automotive standards ISO 26262) or application (e.g., automotive/vehicle technology), current which is <1 mA; <10 mA; 500 μA to 1 mA; <100 μA; a single digit μA current; and/or <50 μA current range may be considered as a “low current”. In comparison to a “low current”, a two-digit Ampere current may be considered a “high current”.

In one or more examples, a control circuitry of a second circuit may comprise a microcontroller. A second circuit may be, for example, a circuit of a vehicle or a part of it, or a circuit of consumable electronics prone to corrosion. Additionally, or alternatively, to control circuitry of a vehicle, the leakage detection of this application can be used for automotive applications in general, such as leakage detection in electric motor drivers.

A microcontroller may refer to a computer device typically on a single integrated circuit that contains a processor core, memory, and programmable input/output peripherals. Input/Output peripherals generally relate to hardware components or devices connectable to the microcontroller, such as sensors, displays, or actuators. A microcontroller is generally used for managing and controlling operations in devices such as home appliances, automotive systems, medical devices, industrial machinery, and consumer electronics, where real-time processing and automation are required.

An ADC stands for an Analog-to-Digital Converter, a device or circuit that transforms an analogue signal, which is continuous in nature, into a digital signal, which is discrete and can be processed by digital electronic systems. An ADC may be used for applications such as converting analogue signals (e.g., measurement current) into digital data (e.g., digitized current), enabling real-time monitoring and control in systems like automotive electronics, industrial machinery, and alike. An ADC may comprise key components such as a sampler to capture the analogue input at discrete intervals, a quantizer to map the sampled values to a finite set of levels, and an encoder to represent these levels in a binary format for digitized output.

The present disclosure will now be described more fully hereinafter with reference to the accompanying drawings, in which embodiments of the disclosure are shown. However, this disclosure should not be construed being limited to the embodiments set forth herein. Rather, these embodiments are provided so that this disclosure will be thorough and complete, and will fully convey the scope of the disclosure to those skilled in the art. Like numbers refer to like elements throughout.

The properties, features and advantages described above and the way in which they are achieved will become clearer and more clearly understood in association with the following description of the exemplary embodiments which are explained in greater detail in connection with the drawings. For simplicity and illustrative purposes, the present disclosure is described by referring mainly to an exemplary embodiment thereof. In the following description, numerous specific details are set forth in order to provide a thorough understanding of the present disclosure. However, it will be readily apparent to one of ordinary skill in the art that the present disclosure may be practiced without limitation to these specific details. In this description, well-known methods and structures have not been described in detail so as not to unnecessarily obscure the present disclosure.

Some examples of the present disclosure generally provide for a plurality of circuits or other electrical devices. All references to the circuits and other electrical devices and the functionality provided by each are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical or electronic devices may be combined with each other and/or separated in any manner based on the particular type of electrical implementation that is desired. It is recognized that any circuit or other electrical or electronic device disclosed herein may include any number of microcontrollers, a graphics processor unit (GPU), integrated circuits, memory devices and software which co-act with one another to perform operation(s) disclosed herein. In addition, any one or more of the electrical or electronic devices may be configured to execute a program code that is embodied in a non-transitory computer readable medium programmed to perform any number of the functions as disclosed.

The drawings are to be regarded as being schematic representations and elements illustrated in the drawings are not necessarily shown to scale. Rather, the various elements are represented such that their function and general purpose become apparent to a person skilled in the art.

Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

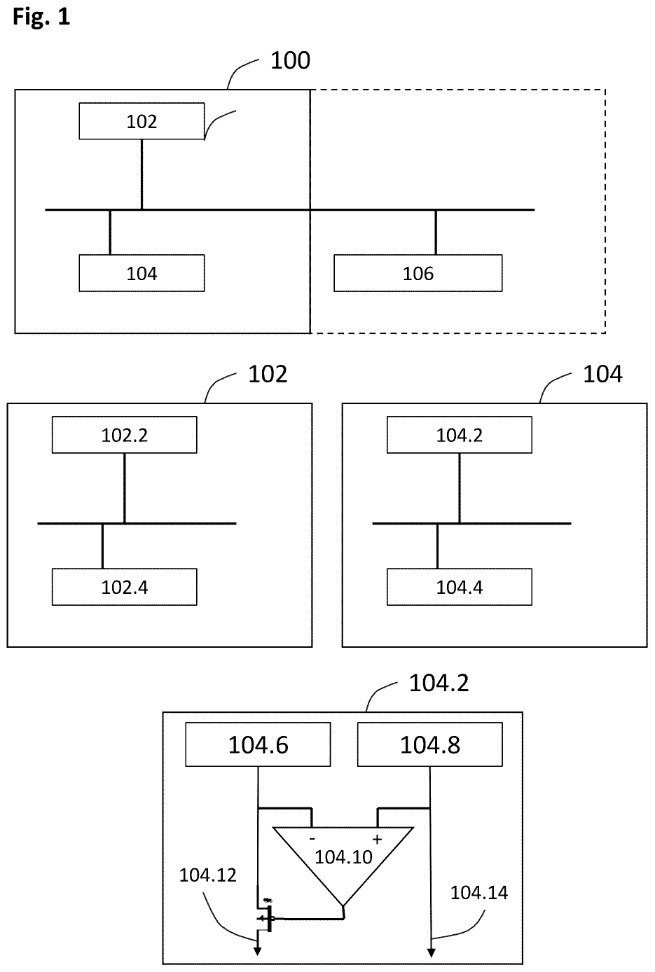

FIG. 1 is a diagram illustrating an electronic circuit 100 for detecting a leakage current in a second circuit.

The electronic circuit 100 comprises timing circuitry 102 and monitoring circuitry 104.

The timing circuitry 102 is configured to automatically activate the monitoring circuitry 104 at time intervals set by the timing circuity 102 to repeatedly measure a measurement current indicative of a leakage.

The monitoring circuitry 104 is configured to compare the measurement current measured at each interval to a leakage threshold current. When the measurement current exceeds the leakage threshold current, the monitoring circuitry 104 is configured to send an indication to control circuitry 106 of the second circuit.

In some examples, the second circuit may be a circuit of a vehicle, such as a power circuit. In some examples, the control circuitry 106 of the second circuit may comprise a microcontroller.

In some examples, the measurement current may be indicative of a current through a power transistor of the second circuit. In some examples, the measurement can be performed in an off state of the power transistor.

In some examples, the power transistor of the second circuit may be integrated with the electronic circuit 100 in a modular assembly or an integrated circuit. The control circuity 106 of the second circuit (e.g., a microcontroller of a vehicle) may communicate with the electronic circuit 100, however, the control circuity 106 may not necessarily be a part of the electronic circuit 100. Electronic circuit 100 may be configured to receive data (e.g., settings 202) from the control circuity 106, and send data (e.g., indication, comparator reporting 204) to the control circuity 106. Therefore, a microcontroller of the control circuitry is not needed for the measurement performed by the timing circuitry and the monitoring circuitry. In other words, the timing circuitry and the monitoring circuitry allow to eliminate the need to involve the control circuitry (e.g., a microcontroller) to monitor leakage current. The control circuitry can stay in a partly active mode during monitoring of leakage current (passive mode) where one or more components of the control circuitry can be switched off. Hence, both, the control circuitry (e.g., a microcontroller) and the second circuit itself (e.g., a power circuit of the vehicle) can operate in a low power mode during the monitoring of leakage current. For example, an electric vehicle can charge its battery during parking (i.e., low power mode), while the electronic circuit (including the timing circuitry and the monitoring circuitry) can monitor the leakage current. The electronic circuit in this case can consume less power during monitoring compared to conventional systems, because the monitoring would occur automatically, triggered by the timer, without the need to have all the components of the control circuit to be active. In conventional systems, monitoring of corrosion is typically implemented by a microcontroller that stays active during the monitoring, meaning that all the components of the microcontrollers are typically involved and stay on. Hence, the approach of this application allows to reduce energy consumption and energy loss during monitoring of leakage current, particularly relevant for electric vehicles.

Returning to FIG. 1, in the exemplary implementation illustrated in FIG. 1, the timing circuitry 102 includes a timer 102.2 and a switch 102.4.

In the exemplary implementation illustrated in FIG. 1, the monitoring circuitry 104 includes measurement circuitry 104.2 and comparator circuitry 104.4.

In the exemplary implementation illustrated in FIG. 1, measurement circuitry 104.2 includes a sense transistor 104.6 and a load transistor 104.8.

In some examples, the gate of the sense transistor 104.6 can be coupled to the gate of the power transistor (load transistor 104.8). The measurement current may be referred to as a current running through the sense transistor 104.6 (sense current 104.12, Isense). More specifically, the measurement current may be indicative of sense current 104.12.1 from a sense transistor 104.6, or sense current provided to comparator circuitry 104.12.2. The measurement current can also indicate load current 104.14, Iload, particularly, a load current 104.14.1 from a load transistor.

Similar to the KILIS (“K”) approach of US 2010/0102845 A1, the sense transistor 104.6 illustrated in FIG. 1 of the application can have a smaller channel area than a channel area of the load transistor 104.8, leading to generating a sense current proportional to the load current in accordance with this difference in the channel area. A current source (not shown in FIG. 1) can be coupled to the sense transistor 104.6 and configured to set the sense current 104.12.

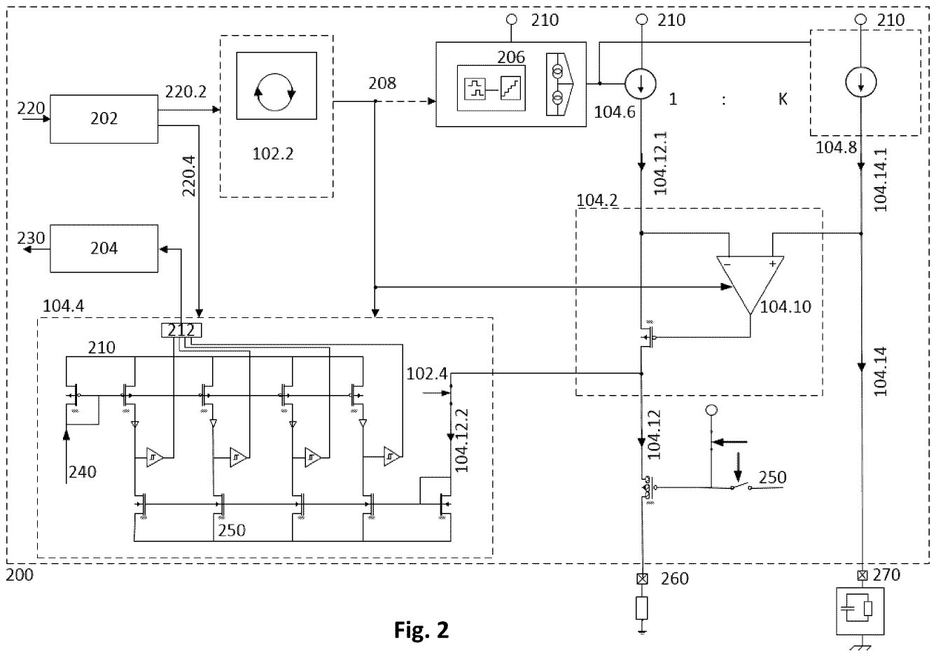

As illustrated in FIG. 1, the measurement circuitry 104.2 can have an operational transconductance amplifier 104.10, OTA, having a non-inverting input coupled to the source of the sense transistor 104.6, and an inverting input coupled to the source of the load transistor 104.8. The OTA can be configured to output the measurement current indicative of the leakage, which, in turn, can indicate a corrosion state. The OTA can be configured to regulate the sense current such that the sense current maintains a fixed ratio (“K” ratio) with the load current. The fixed ratio (“K” ratio) of the load current to the sense current can be determined by a geometric area ratio of the channel area of the load transistor to the channel area of the sense transistor. This “K” ratio is further illustrated in FIG. 2, “1:K”.

In some examples, the monitoring circuitry 104 can further comprise comparator circuitry 104.4, as illustrated in FIG. 1. The comparator circuitry 104.4 can be configured to compare the measurement current to the leakage threshold current.

FIG. 2 is a more detailed diagram (as to the one in FIG. 1) illustrating an electronic circuit 200 for detecting a leakage current in a second circuit.

Hence, the reference signs and components described in the context of FIG. 1 are also applicable to FIG. 2. Thus, the electronic circuit 200 may be understood as an exemplary implementation of electronic circuit 100 described in the context of FIG. 1.

In some examples, a system can comprise electronic circuit 100 or electronic circuit 200, and a second circuit having control circuitry 106.

The system can further comprise a high side switch, HSS, or a bypass device of a vehicle supplying current to a load of the vehicle. The monitoring circuitry can be configured to monitor a leakage state of the high side switch or the bypass device of the vehicle by comparing the measurement current and the leakage threshold current. The HSS or the bypass device can include a load transistor 104.8, which may also be referred to as a power transistor.

As illustrated in FIG. 2, supply voltage 210 can be applied to the load transistor 104.8, sense transistor 104.6, and a power stage 206 of a vehicle.

In some examples, comparator circuitry 104.4 can further include an analogue to digital convertor, ADC. As illustrated in FIG. 2, the ADC can have an encoder 212 and can receive a supply voltage 210 and a reference current 240. The ADC can have a ground or floating supply connection 250. The ADC can be configured to convert the measurement current from an analogue current to a digitized current, and compare the digitized current to the leakage threshold current. When the measurement current exceeds the leakage threshold current, the comparator circuitry 104.4 can be configured to send the indication to the control circuitry 106 of the second circuit. Sending the indication may be referred to as comparator reporting 204. Such a reporting can provide an interruption request 230 (IRQ) to control circuitry 106. The circuit 200 can receive (at point 220 in FIG. 2) settings 202 from control circuitry 106. Settings 202 received from 106 can comprise timing settings 202.2 and threshold settings 202.4. Timing settings 202.2 can be provided to a timer 102.2 and the timer signal can be diagnosed (at point 208 in FIG. 2) with respect to the timing setting 202.2. Based on the measurement of the measurement current, the encoder 212 can provide an interruption request 230 to control circuitry 106. The circuit 200 can further comprise an output sensing pin 260 and an output load 270. The circuit 200 can further comprise switches 102.4 for activating the monitoring circuitry 104.

Hence, in some examples, the monitoring circuitry 104 of the electronic circuit 200 can be further configured to receive at least one of timing settings 202.2 and threshold settings 202.4 from the control circuitry 106 of the second circuit. Such an arrangement provides flexibility so that monitoring of leakage current can be tailored to an application. For example, different intervals and/or measurement durations may be chosen based on, e.g., expected levels of corrosion, and/or energy consumption during monitoring.

The threshold settings can comprise a value of the leakage threshold current. The timing settings can comprise at least one of a frequency of the time intervals for activating the monitoring circuitry 104, and a measurement duration for measuring the measurement current.

In some examples, the monitoring circuitry 104 of the electronic circuit 200 can be further configured to be coupled to a high side switch, HSS, or a bypass device of a vehicle supplying current to a load 270 of the vehicle. The monitoring circuitry 104 can be further configured to monitor a leakage state of the HSS or the bypass device of the vehicle by comparing the measurement current and the leakage threshold current.

As may be understood from the above, an HSS may comprise a power transistor such as a high-speed switching transistor. However, monitoring leakage current may also be performed for a non-high-speed switching power transistor. A non-high-speed switching power transistor may refer to a power transistor that is not specifically designed for high-speed switching applications. Unlike high-speed switching transistors, which typically operate at very high frequencies to rapidly switch power on and off, non-high-speed switching power transistors are typically optimised for lower speed switching or continuous operation. These transistors are often used in applications where switching speed is less critical, such as a steady-state power control (managing constant current or voltage in circuits). For example, a non-high-speed switching power transistor may be a MOSFET transistor specifically designed for robust, low-speed operations rather than fast transient responses.

In some examples, a vehicle can comprise the electronic circuit 200 or the system including the electronic circuit 200 and the second circuit having control circuity 106.

In some examples, electronic circuit 200 or 100 can be used for leakage current detection in a vehicle.

In some examples, the system (comprising the electronic circuit 200 and the second circuit having control circuity 106) can be used for leakage current detection in a vehicle.

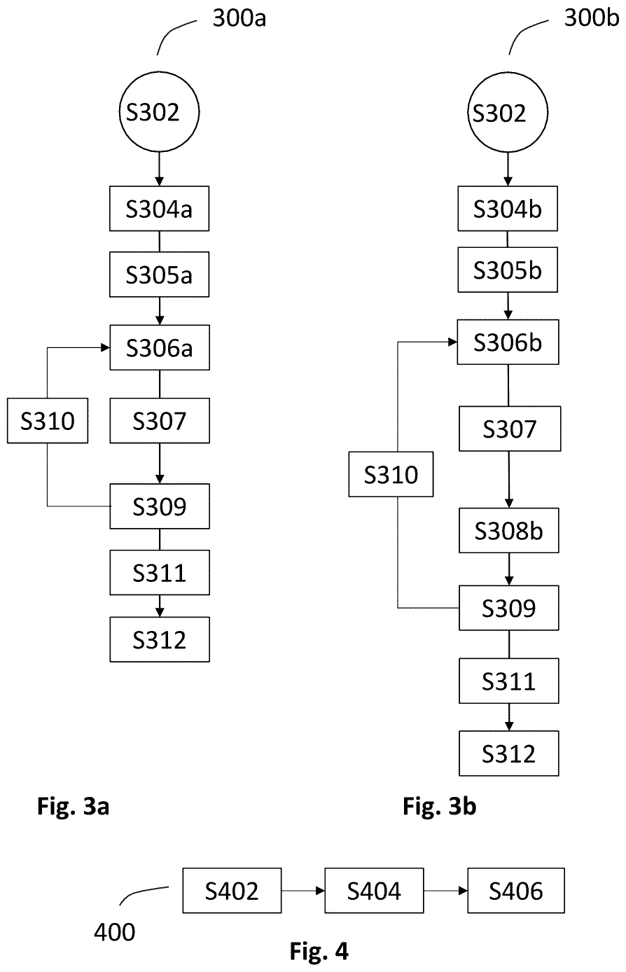

FIG. 3a is a flowchart of a method 300a according to an embodiment.

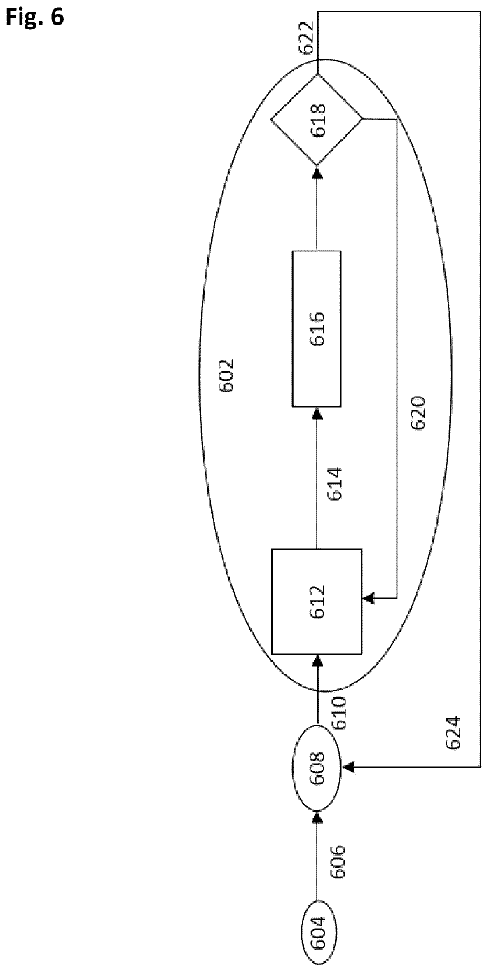

The method 300a is an exemplary implementation of a method to monitor an increased leakage current. In this implementation, the HSS or Bypass device are set in a low power mode (idle mode) wherein still an idle current is supplied to the load. Via configurable internal self-cycling the monitoring can be activated to sense load current via, e.g., an ADC. Such an internal self-cycling can be implemented by the timing timing circuitry 102 described in the context of FIG. 1. The self-cycling is further described in the context of state diagram 600 in FIG. 6, specifically, by self-cycling 602 loop. Returning to FIG. 3a, in case the measured current exceeds the threshold leakage current, the monitoring circuitry can communicate this to a higher-level communication (control circuitry of a second circuit, wherein the control circuitry can comprise a microcontroller).

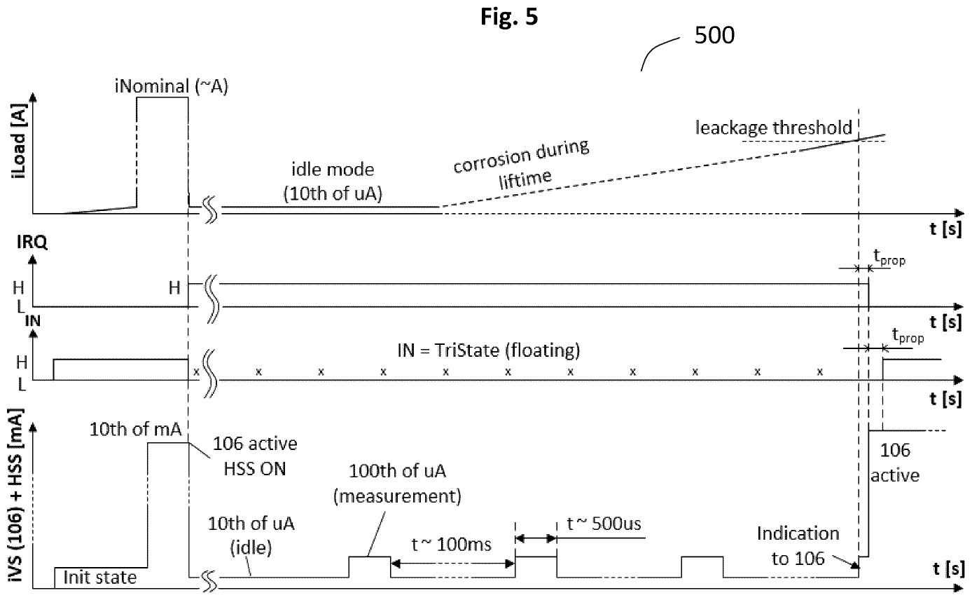

Method 300a comprises the following steps:
(S302) setting input signal to logical “1” or high “H” (INx=“1”); wherein setting the initial state to H is further illustrated in the timing diagram in FIG. 5, where H is set to “IN” pin before the idle mode occurs; H state enables internal wake up of the timer;
(S304a) switching a DMOS transistor ON which enables the operation of the sense transistor to measure the measurement current, as described in the context of FIG. 2;
(S305a) checking whether low power mode conditions of the HSS or Bypass device are satisfied; which can be implemented by comparing the measurement current to an idle mode current, as further illustrated in the timing diagram in FIG. 5, where idle mode starts but corrosion during lifetime is not yet happening;
(S306a) activating the monitoring circuitry at time intervals set by the timing circuity to repeatedly measure a measurement current; when idle mode is entered, this triggers the measurement of the measurement current until the measurement current reaches the leakage threshold or a time interval exceeds a value of the timing settings;
(S307) checking whether the time interval exceeds the value of the timing settings;
(S309) measuring the measurement current when the time interval exceeds the value;
(S310) when the measurement current does not exceed the leakage threshold current (ILoad<Ithreshold), continuing repeatedly measuring the measurement current at the time intervals;
(S311) checking whether the measurement current exceeds the leakage threshold current (ILoad>Ithreshold); and
(S312) when the measurement current exceeds the leakage threshold current (ILoad>Ithreshold), sending an indication to the control circuitry.

In the exemplary implementation illustrated by FIG. 3a, a power transistor is implemented as a DMOS transistor.

Checking whether low power mode conditions, setting up logical high and low states, and the comparison of ILoad to Ithreshold is further described in the timing diagram 500 in the context of FIG. 5.

FIG. 3b is a flowchart of a method 300b according to an embodiment.

The method 300b is another exemplary implementation of a method for monitoring an increased leakage current. This method is similar to method 300a. The similarity can be seen in steps S302, S307, S310, S309, S311 and S312. The difference between 300a and 300 b is in that there is no low power mode (idle mode) in 300b. This means that via the internal self-cycling (as further illustrated by self-cycling loop 602 in FIG. 6), the DMOS transistors must be switched ON by the timer to sense the measurement current via, e.g., a comparator, which may include an ADC. The comparator (as described in FIG. 2 by comparator reporting 204) can then communicate with the control circuitry (microcontroller) in the same way, as in method 300a.

Hence, method 300b may be summarized by the following steps (S302) setting input signal to logical 1 (INx=“1”) which is an identical step to S302 in method 300a;
(S304b) switching a DMOS transistor OFF, which is an alternative step to entering the idle mode in method 300a and is necessary to configure cyclic wake in the subsequent step S305b;
(S305b) configuring cyclic wake up by timing circuity;
(S306b) activating the monitoring circuitry at time intervals set by the timing circuity to repeatedly measure a measurement current;
(S307) checking whether a time interval exceeds a value of the timing settings;
(S308b) switching the DMOS transistor ON, which enables the operation of the sense transistor to measure the measurement current, as described in the context of FIG. 2;
(S309) when the time interval does not exceed the value of the timing settings, measuring the measurement current until the time interval exceeds the value or the measurement current, iLoad, reaches the leakage threshold current, Ithreshold;
(S310) when the measurement current does not exceed the leakage threshold current (ILoad<Ithreshold), continue repeatedly measuring the measurement current at the time intervals;
(S311) checking whether the measurement current exceeds the leakage threshold current (ILoad>Ithreshold); and
(S312) when the measurement current exceeds the leakage threshold current (ILoad>Ithreshold), sending an indication to the control circuitry.

The cyclic wake of step S305b can be implemented by a timer 102.2 and switch 102.4. The comparison of ILoad to Ithreshold of Steps S310 and S311 is further illustrated in the timing diagram 500 in FIG. 5.

FIG. 4 Is a flowchart of a method 400 according to an embodiment.

The method 400 to be carried out by an electronic circuit 100 or 200, wherein the electronic circuit comprises timing circuitry 102 and monitoring circuitry 104, the method comprising the following steps (S402, S404, S406):
(S402) automatically activating the monitoring circuitry, by the timing circuitry, at time intervals set by the timing circuity to repeatedly measure a measurement current indicative of a leakage; and
(S404) comparing, by the monitoring circuitry, the measurement current measured at each interval to a leakage threshold current indicative of a leakage state,
(S406) sending an indication by the monitoring circuitry to control circuitry of a second circuit when the measurement current exceeds the leakage threshold current.

Hence, method 400 is a more general implementation of methods 300a and 300b described in the context of FIGS. 3a and 3b.

In some examples, the measurement current provided by method 400 may be indicative of a load current through a power transistor of the second circuit, and the measurement may be performed in an off state of the power transistor.

In some examples, method 400 may further comprise: detecting a low power mode when the load current through the power transistor changes from a nominal load current to a low power mode current defined by a low power mode threshold current, wherein the automatically activating and the comparing is performed only in the low power mode.

In some examples, method 400 may further comprise: automatically deactivating the monitoring circuitry by the timing circuitry, when the load current changes back from the low power mode current to the nominal load current. More specifically, automatic activation may be implemented by an electronic timer (such as the one illustrated in FIGS. 1 and 2, timer 102.2) and one or more automatic switches (such as the one illustrated in FIGS. 1 and 2, switch 102.4). Hence, timing circuitry may comprise a timer and one or more automatic switches.

A timer 102.2 may be a synchronous timer based on SPI clock signal, an asynchronous timer that operates independently of the SPI clock signal, a low-power timer based on SPI clock signal, a self-cyclical timer that operates in a continuous loop (such as self-cycling loop 602 in FIG. 6).

An SPI may refer to the Serial Peripheral Interface, a synchronous serial communication protocol commonly used to enable high-speed data exchange between control circuitry (a microcontroller) and peripheral devices (timing and monitoring circuitry). SPI is particularly suited for systems that require a master-slave architecture with minimal wiring. SPI may comprise four main lines: a clock signal (SCLK) generated by the master to synchronize communication, a master output/slave input (MOSI) line for data transfer from the master to the slave, a master input/slave output (MISO) line for data transfer from the slave to the master, and a slave select (SS) line to activate the desired slave device.

A synchronous timer based on SPI may refer to a timer that operates in synchronization with the SPI clock signal. A synchronous timer may rely on the SPI clock (SCLK) to coordinate its timing functions, ensuring precise timing intervals relative to the clock edges of SPI communication.

An asynchronous timer may refer to a timer that operates independently of the SPI clock signal. An asynchronous timer may function based on an internal clock or another external timing source, allowing it to perform timing operations without being tied to the SPI communication cycle. An asynchronous timer may be used for general-purpose timing, periodic interrupts, or time-based events that are not dependent on SPI activity.

A low-power timer based on SPI may refer to a timer specifically designed to consume minimal power while performing timing functions. A low-power timer may be implemented in battery-operated or energy-sensitive devices such as electric vehicles or consumable electronics. A low-power timer based on SPI may be configured to run at reduced clock speeds or use energy-efficient circuitry. Such a low-power timer may be used for maintaining timekeeping, generating periodic wake-up signals, as for example, further illustrated by the timing diagram 500 in FIG. 4.

A self-cyclical timer may refer to a timer that operates in a continuous loop (such as self-cycling 602 loop further illustrated in FIG. 6), automatically restarting itself upon completing a timing cycle. A self-cyclical timer may be designed to generate periodic wake-up events or actions without requiring external intervention to reset or restart the timer.

Returning to method 400, in some examples, the method 400 may further comprise: comparing, by a comparator of the monitoring circuitry, the measurement current to the leakage threshold current.

In some examples, method 400 may further comprise: converting, by an analogue to digital convertor, ADC, of the monitoring circuitry, the measurement current from an analogue current to a digitized current, comparing, by the ADC, the digitized current to the leakage threshold current, wherein when the measurement current exceeds the leakage threshold current, sending, by the ADC, the indication to the control circuitry of the vehicle comprising a microcontroller, wherein the indication comprises an interruption request, IRQ, for activating the microcontroller of the control circuitry.

In some examples, method 400 may further comprise: receiving, by the monitoring circuitry, from the control circuitry, at least one of timing settings and threshold settings,
wherein the threshold settings comprise a value of the threshold current, and
wherein the timing settings comprise at least one of a frequency of the time intervals for activating the monitoring circuitry, and a measurement duration for measuring the control current.

FIG. 5 Is a timing diagram 500 according to an embodiment.

The timing diagram 500 relates to the operation of electronic circuit 100 or 200 according to FIG. 1 or 2, respectively.

In some examples, the timing circuitry 102 can be further configured to automatically activate the monitoring circuitry 104 by detecting a low power mode when a load current 104.14 through the power transistor changes from a nominal load current (“iNominal” in an order of amperes, ~A) to a low power mode current defined by a low power mode threshold current (idle mode current in the range of double-digit microampere current, 10th of uA). The measurement circuitry 104.2 can be configured to repeatedly measure and compare the measurement current only in the low power mode (i.e., the “idle mode” illustrated in the diagram 500). As corrosion develops, a leakage current increases, adding to the low power mode threshold current until the “iLoad” reaches a leakage threshold current. In this case, the control circuitry can be notified by an interruption request, IRQ, and a pin of a control circuitry can be set from logical low state “L” to logical high state “H”. Current consumed by the control circuitry (iVS+HSS) can be in an order of tenths (10th) of uA in an initial state and an idle mode, increasing to hundreds (100th) of uA during the measurement. If a notification is sent to the control circuitry, this wakes up the control circuitry from the idle mode to a fully active mode with a propagation time delay (t_prop). Hence, when the measurement current exceeds the leakage threshold current, by sending the notification to the control circuitry, the timing circuitry activates at least a part of the control circuitry.

As illustrated in the diagram 500, when the control circuitry wakes up, its current consumption typically increases to tens (10th) of mA. During the idle mode, automatic monitoring can be triggered by setting an input pin (IN) from logical high H to triple floating state x. After the notification is sent to the control circuitry about a leakage exceeding leakage threshold, IN can be set back to H. In some examples, the measurement can last, e.g., 500 us, and the interval between measurements can be, e.g., 100 ms. The interval (e.g., 100 ms) and the measurement duration (e.g., 500 us) can be provided as timing settings (settings 202.2 in FIG. 2). This way, the control circuitry 106 does not need to stay fully active all the time during the idle mode, requiring the current in the range of tens (10th) of mA. This way, the control circuitry 106 can only consume hundreds (100th) of uA during the measurement of the measurement current, in comparison to being fully awake and consuming tens (10th) of mA. In this way, the current consumption during monitoring of leakage current can be reduced since some parts of the control circuitry can be switched off.

In some examples, the timing circuitry 102 can be further be configured to automatically deactivate the monitoring circuitry 104 when the load current iLoad changes back from the low power mode current (illustrated as “idle mode” in FIG. 5) to the nominal load current (illustrated as “iNominal” in FIG. 5). Hence, monitoring of the leakage current can be fully automated, reducing the power consumption induced by the monitoring even further.

In some examples, a leakage state can be indicative of a corrosion state. In FIG. 5, load current, “iLoad”, changing from idle mode current to the current indicated as “corrosion during lifetime” can indicate active corrosion state. iLoad increasing above the leakage threshold can indicate dangerous corrosion state which can result in a serious failure of the circuit, e.g., a fire.

FIG. 6 is a state diagram 600 according to an embodiment.

The state diagram 600 relates to the operation of electronic circuit 100 or 200 described in the context of FIG. 1 or 2, respectively.

In the diagram 600, self-cycling 602 includes automatically activating 612 the monitoring circuitry, and subsequently, checking 614 whether a time interval exceeds a value of the timing settings. The self-cycling 602 then proceeds to measuring 616 the measurement current and comparing 618, by the monitoring circuitry, the measurement current measured (ILoad) at each interval to a leakage threshold current (Ithreshold) indicative of a leakage state.

The self-cycling 602 then proceeds to checking the condition 620 whether ILoad<Ithreshold, and if so, self-cycling 602 loop resets the time interval and repeats measuring the measurement current.

Initial state in the timing diagram corresponds to the initial state 604. In this initial state 604 initial settings 606 can be set (e.g., “H” state of an input pin). At the start of the self-cycling 602 loop nominal mode 608 can be verified, for example, by checking 610 whether low power mode conditions are satisfied (e.g., this can be done by checking nominal current, iNominal, described in the timing diagram 500). If so, this means that the low power mode (idle mode) is entered, and the self-cycling 602 loop starts by the automatic activation 612 until checking the state 622 where ILoad>Ithreshold is reached. When this state is reached, ILoad>Ithreshold, an indication is sent (624) to the control circuitry 106 by setting an IRQ pin of the control circuitry to a logical high “H” state.

Some embodiments are defined by the following examples:
Example 1. An electronic circuit for detecting a leakage current in a second circuit, the electronic circuit comprising:
timing circuitry and monitoring circuitry;
wherein the timing circuitry is configured to automatically activate the monitoring circuitry at time intervals set by the timing circuity to repeatedly measure a measurement current indicative of a leakage; and
wherein the monitoring circuitry is configured to compare the measurement current measured at each interval to a leakage threshold current, wherein when the measurement current exceeds the leakage threshold current, the monitoring circuitry is configured to send an indication to control circuitry of the second circuit.

Example 2. The electronic circuit of Example 1, wherein the measurement current is indicative of a current through a power transistor of the second circuit, and wherein the measurement is performed in an off state of the power transistor.

Example 3. The electronic circuit of Example 2, wherein the power transistor of the second circuit is integrated with the electronic circuit in a modular assembly or an integrated circuit.

Example 4. The electronic circuit of Example 2 or 3, wherein the monitoring circuitry comprises:
a sense transistor having a gate coupled to the gate of the power transistor, wherein the measurement current is a current through the sense transistor.

Example 5. The electronic circuit of Example 4,
wherein the timing circuitry is further configured to automatically activate the monitoring circuitry by detecting a low power mode when a load current through the power transistor changes from a nominal load current to a low power mode current defined by a low power mode threshold current;
wherein the monitoring circuitry is configured to repeatedly measure and compare the measurement current only in the low power mode.

Example 6. The electronic circuit of Example 5,
wherein the timing circuitry is further configured to automatically deactivate the monitoring circuitry when the load current changes back from the low power mode current to the nominal load current.

Example 7. The electronic circuit of any one of the preceding Examples,
wherein the monitoring circuitry comprises comparator circuitry including comparator circuitry configured to compare the measurement current to the leakage threshold current.

Example 8. The electronic circuit of Example 7, wherein the comparator circuitry further includes an analogue to digital convertor, ADC, configured to:
convert the measurement current from an analogue current to a digitized current,
compare the digitized current to the leakage threshold current, wherein
when the measurement current exceeds the leakage threshold current, the comparator circuitry is configured to send the indication to the control circuitry of the second circuit.

Example 9. The electronic circuit of any one of the preceding Examples,
wherein the monitoring circuitry is further configured to receive at least one of timing settings and threshold settings from the control circuitry of the second circuit,
wherein the threshold settings comprise a value of the leakage threshold current, and
wherein the timing settings comprise at least one of a frequency of the time intervals for activating the monitoring circuitry, and a measurement duration for measuring the measurement current.

Example 10. The electronic circuit of any one of Examples 2-9,
wherein the monitoring circuitry is configured to be coupled to a high side switch, HSS, or a bypass device of a vehicle supplying current to a load of the vehicle, and wherein the monitoring circuitry is configured to monitor a leakage state of the HSS or the bypass device of the vehicle by comparing the measurement current and the leakage threshold current.

Example 11. The electronic circuit of Example 10, wherein the leakage state is indicative of a corrosion state.

Example 12. the electronic circuit of any one of examples 1 to 11,
wherein the timing circuitry is configured to activate at least part of the control circuitry when the measurement current exceeds the leakage threshold current.

Example 13. A system comprising the electronic circuit according to any one of the preceding Example and the second circuit.

Example 14. The system of Example 13 further comprising a high side switch, HSS, or a bypass device of a vehicle supplying current to a load of the vehicle, and wherein the monitoring circuitry is configured to monitor a leakage state of the high side switch or the bypass device of the vehicle by comparing the measurement current and the leakage threshold current.

Example 15. A vehicle, comprising the electronic circuit of any one of Example 1-12 or the system of any one of Example 13-14.

Example 16. Use of the electronic circuit according to any one of Example 1-12 for an automotive application, optionally, comprising leakage current detection in a vehicle.

Example 17. Use of the system according to any one of Examples 13-14 for an automotive application, optionally, comprising leakage current detection in a vehicle.

Example 18. A method to be carried out by an electronic circuit, wherein the electronic circuit comprises timing circuitry and monitoring circuitry, the method comprising:
automatically activating the monitoring circuitry, by the timing circuitry, at time intervals set by the timing circuity to repeatedly measure a measurement current indicative of a leakage; and
comparing, by the monitoring circuitry, the measurement current measured at each interval to a leakage threshold current indicative of a leakage state,
sending an indication by the monitoring circuitry to control circuitry of a second circuit when the measurement current exceeds the leakage threshold current.

Example 19. The method of Example 18, wherein the measurement current is indicative of a load current through a power transistor of the second circuit, and the measurement is performed in an off state of the power transistor.

Example 20. The method of Example 19 further comprising:
detecting a low power mode when the load current through the power transistor changes from a nominal load current to a low power mode current defined by a low power mode threshold current,
wherein the automatically activating and the comparing is performed only in the low power mode.

Example 21. The method of Example 20 further comprising:
automatically deactivating the monitoring circuitry by the timing circuitry, when the load current changes back from the low power mode current to the nominal load current.

Example 22. The method of any one of examples 18-21 further comprising:
comparing, by a comparator of the monitoring circuitry, the measurement current to the leakage threshold current.

Example 23. The method of Example 22 further comprising:
converting, by an analogue to digital convertor, ADC, of the monitoring circuitry, the measurement current from an analogue current to a digitized current,
comparing, by the ADC, the digitized current to the leakage threshold current, wherein
when the measurement current exceeds the leakage threshold current, sending, by the ADC, the indication to the control circuitry of the vehicle comprising a microcontroller, wherein the indication comprises an interruption request, IRQ, for activating the microcontroller of the control circuitry.

Example 24. The method of any one of Examples 18-23 further comprising:
receiving, by the monitoring circuitry, from the control circuitry, at least one of timing settings and threshold settings,
wherein the threshold settings comprise a value of the threshold current, and
wherein the timing settings comprise at least one of a frequency of the time intervals for activating the monitoring circuitry, and a measurement duration for measuring the control current.

The methods and systems of current sensing in electronic circuits summarised by the above Examples may be particularly advantageous for monitoring leakage current in control circuitry prone to corrosion. The methods and the systems of the current application allow to monitor leakage current in power circuits with reduced power consumption of the monitoring circuits, while providing a robust measurement of low leakage current in contrast to high current through a load of the power circuits. Reduced power consumption by the monitoring circuitry, operating automatically through the timing circuitry, can contribute to energy saving. Hence, energy loss of the current monitoring systems may be mitigated by the embodiments of the application.

Example 25. Use of the method according to any one of Examples 18-24 for an automotive application, optionally, comprising leakage current detection in a vehicle.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. An electronic circuit for detecting a leakage current in a second circuit, the electronic circuit comprising:
timing circuitry and monitoring circuitry;
wherein the timing circuitry is configured to automatically activate the monitoring circuitry at time intervals set by the timing circuity to repeatedly measure a measurement current indicative of a leakage; and
wherein the monitoring circuitry is configured to compare the measurement current measured at each interval to a leakage threshold current, wherein when the measurement current exceeds the leakage threshold current, the monitoring circuitry is configured to send an indication to control circuitry of the second circuit.

2. The electronic circuit of claim 1, wherein the measurement current is indicative of a current through a power transistor of the second circuit, and wherein the measurement is performed in an off state of the power transistor.

3. The electronic circuit of claim 2, wherein the power transistor of the second circuit is integrated with the electronic circuit in a modular assembly or an integrated circuit.

4. The electronic circuit of claim 2, wherein the monitoring circuitry comprises:
a sense transistor having a gate coupled to the gate of the power transistor, wherein the measurement current is a current through the sense transistor.

5. The electronic circuit of claim 4,
wherein the timing circuitry is further configured to automatically activate the monitoring circuitry by detecting a low power mode when a load current through the power transistor changes from a nominal load current to a low power mode current defined by a low power mode threshold current;
wherein the monitoring circuitry is configured to repeatedly measure and compare the measurement current only in the low power mode.

6. The electronic circuit of claim 5,
wherein the timing circuitry is further configured to automatically deactivate the monitoring circuitry when the load current changes back from the low power mode current to the nominal load current.

7. The electronic circuit of claim 1,
wherein the monitoring circuitry comprises comparator circuitry including comparator circuitry configured to compare the measurement current to the leakage threshold current.

8. The electronic circuit of claim 7, wherein the comparator circuitry further includes an analog to digital convertor configured to:
convert the measurement current from an analogue current to a digitized current,
compare the digitized current to the leakage threshold current, wherein
when the measurement current exceeds the leakage threshold current, the comparator circuitry is configured to send the indication to the control circuitry of the second circuit.

9. The electronic circuit of claim 1,
wherein the monitoring circuitry is further configured to receive at least one of timing settings and threshold settings from the control circuitry of the second circuit,
wherein the threshold settings comprise a value of the leakage threshold current, and
wherein the timing settings comprise at least one of a frequency of the time intervals for activating the monitoring circuitry, and a measurement duration for measuring the measurement current.

10. The electronic circuit of claim 2,
wherein the monitoring circuitry is configured to be coupled to a high side switch, HSS, or a bypass device of a vehicle supplying current to a load of the vehicle, and wherein the monitoring circuitry is configured to monitor a leakage state of the HSS or the bypass device of the vehicle by comparing the measurement current and the leakage threshold current.

11. The electronic circuit of claim 10, wherein the leakage state is indicative of a corrosion state.

12. The electronic circuit of claim 1,
wherein the timing circuitry is configured to activate at least part of the control circuitry when the measurement current exceeds the leakage threshold current.

13. A system comprising:
an electronic circuit and a second circuit, wherein the electronic circuit is configured to detect a leakage current in a second circuit;
wherein the electronic circuit comprises:
timing circuitry and monitoring circuitry,
wherein the timing circuitry is configured to automatically activate the monitoring circuitry at time intervals set by the timing circuity to repeatedly measure a measurement current indicative of a leakage, and
wherein the monitoring circuitry is configured to compare the measurement current measured at each interval to a leakage threshold current, wherein when the measurement current exceeds the leakage threshold current, the monitoring circuitry is configured to send an indication to control circuitry of the second circuit.

14. The system of claim 13 further comprising a high side switch or a bypass device of a vehicle supplying current to a load of the vehicle, and wherein the monitoring circuitry is configured to monitor a leakage state of the high side switch or the bypass device of the vehicle by comparing the measurement current and the leakage threshold current.

15. A method performed by an electronic circuit, wherein the electronic circuit comprises timing circuitry and monitoring circuitry, the method comprising:
automatically activating the monitoring circuitry by the timing circuitry, at time intervals set by the timing circuity to repeatedly measure a measurement current indicative of a leakage; and
comparing, by the monitoring circuitry, the measurement current measured at each interval to a leakage threshold current indicative of a leakage state,
sending an indication by the monitoring circuitry to control circuitry of a second circuit when the measurement current exceeds the leakage threshold current.

16. The method of claim 15,
wherein the measurement current is indicative of a load current through a power transistor of the second circuit, and the measurement is performed in an off state of the power transistor.

17. The method of claim 16 further comprising:
detecting a low power mode when the load current through the power transistor changes from a nominal load current to a low power mode current defined by a low power mode threshold current,
wherein the automatically activating and the comparing is performed only in the low power mode.

18. (canceled)
